(19) United States
(12) Patent Application Publication
(10) Pub. No.: US 2006/0273400 A1
(43) Pub. Date: Dec. 7, 2006

(54) High voltage analog switch ICS and ultrasound imaging systems using same

(75) Inventors: Taiga Arai, Chiyoda-ku (JP); Junichi Sakano, Chiyoda-ku (JP)

Correspondence Address: CROWELL & MORING LLP;INTELLECTUAL PROPERTY GROUP, P.O. BOX 14300, WASHINGTON, DC, 20044-4300, US

(73) Assignee: Hitachi, Ltd., Chiyoda-ku (JP)

(21) Appl. No.: 11/350,930

(22) Filed: Feb. 10, 2006

(30) Foreign Application Priority Data
Jun. 1, 2005 (JP) 2005-160851

(51) Int. Cl. H01L 29/94

(52) U.S. Cl. 257/368

(57) ABSTRACT

A MOSFET including a JFET resistor resultant between a drain region and a channel region caused by depletion of current carriers. Since most of the drain-source voltage is imposed on the JFET resistor, the voltage imposed on a channel region is reduced to prevent concentration of an electric field therein. The JFET resistor adjusts the saturation current of the MOSFET and hence the width of the gate electrode can be sufficiently secured. This also prevents concentration of an electric field onto the channel region. In the MOSFET, the saturation current is reduced while avoiding creation of hot carriers. It is therefore possible to provide an MOSFET suitable for an analog switch.

### BACKGROUND OF THE INVENTION

The present invention relates to a semiconductor device suitable for a high-voltage analog switch, and in particular, to a semiconductor device suitable for conducting a change-over operation between transmission and reception of a vibrator in an ultrasound imaging system.

Systems such as an ultrasound imaging system and a printer include a plurality of switches to produce a desired input/output plotted image by individually driving the respective switches. To use a large number of switches of this type arranged in parallel connection at a highly integrated configuration, an analog switch integrated circuit (to be referred to as an analog switch IC herein below) using semiconductors has been employed. JP-A-2004-363997 describes an ultrasound imaging system adopting such analog switch ICs.

When such an analog switch IC used in the ultrasound imaging system conducts a change-over operation between a conductive state and a non-conductive state in response to reception of a control signal, noise takes place due to a leakage current from a drive circuit driving the analog switch IC depending on cases. To overcome this difficulty, an element having a small saturation current is adopted as the drive circuit to reduce the leakage current from the drive circuit to thereby produce an output with lower noise.

An analog switch IC includes a field effect bipolar transistor with metal oxide semiconductor (MOS) gate (to be referred to as an MOSFET hereinbelow). The MOSFET is a switching element to control a current flowing between a drain electrode and a source electrode according to a voltage applied to a gate electrode. The MOSFET has a characteristic in which when the drain-source voltage is increased with the gate voltage kept at a fixed value, the drain current monotonously increases with a low drain-source voltage and saturates with a voltage equal to or more than a predetermined value. To enhance the countermeasure against the noise, it is a common practice to narrow the width of the gate electrode to resultantly produce an MOSFET having a reduced saturation current.

FIG. 2A shows an n-type channel MOSFET on an n⁻-type silicon substrate in a plan view. FIG. 2B is a cross-sectional view of the MOSFET along line BB′ of FIG. 2A. FIGS. 2A and 2B include a drain terminal 1, a source terminal 2, a gate terminal 3, a semiconductor device 20, an n⁻-type silicon substrate 100, a p-type channel layer 110, a source electrode contact layer 120, a drain electrode contact layer 121, an insulation oxide film 130, a source electrode 131, a drain electrode 132, and a gate electrode 133. Since a current path through the p-type channel layer 110 is only a charge inversion layer (channel region) formed beneath the gate electrode 133, the saturation current can be reduced by narrowing the width of the gate electrode 133 as shown in FIG. 2A.

FIG. 3A is a plan view similarly showing a p-type channel MOSFET on an n⁻-type silicon substrate. FIG. 3B is a cross-sectional view of the MOSFET along line CC′ of FIG. 3A. The configurations shown in FIGS. 3A and 3B include a drain terminal 1, a source terminal 2, a gate terminal 3, a semiconductor device 30, an n⁻-type silicon substrate 200, an n-type channel layer 210, a source electrode contact layer 220, a drain electrode contact layer 221, a p⁻-type drift layer 223, an insulation oxide film 230, a source electrode 231, a drain electrode 232, and a gate electrode 233. By narrowing the width of the gate electrode 233 as shown in FIG. 3A, the saturation current can be reduced.

### SUMMARY OF THE INVENTION

When the width of the gate electrode of the MOSFET becomes narrower, the current and/or the electric field are/is concentrated onto the channel region as the current path beneath the gate electrode depending on cases. The current and/or the electric field concentrated as above lead/leads to creation of high-energy hot carriers. When the hot carriers are injected into the gate oxide film, the film is deteriorated. This causes aging of the MOSFET, namely, a change thereof with the passage of time, leading to, for example, a change in the threshold value voltage of the MOSFET. As a result, the characteristic of the analog switch IC becomes unstable to resultantly affect stability of performance of the ultrasound imaging device including the analog switch IC.

It is therefore an object of the present invention to provide an MOSFET for a small-sized analog switch including high voltage gates in which the saturation current of the MOSFET is reduced while suppressing creation of hot carriers.

In the MOSFET according to the present invention, a resistive region appearing due to a depletion phenomenon of current carriers is disposed between a drain region and a channel region. For the resistive region, there is employed a Junction-FET (JFET) resistor formed by a carrier depletion layer which extends from a junction boundary interface or plane when an n-type region side of a semiconductor junction between a p-type region and an n-type region is at a higher electric potential.

In the MOSFET with an integrated JFET resistor according to the present invention, since the JFET resistor is loaded with most of the drain-source voltage, the voltage imposed on the channel region is reduced and hence the electric field is not concentrated therein. Since the JFET current is used to adjust the saturation current, the width of the gate electrode can be sufficiently secured and the current concentration onto the channel region is also avoided.

According to the present invention, since the voltage imposed on the JFET resistor suppresses creation of hot carriers, the aging of the semiconductor device is reduced. This hence guarantees high reliability of the analog switch IC and the ultrasound imaging system using the same.

### BRIEF DESCRIPTION OF THE DRAWINGS

FIGS. 1A and 1B are a plan view and a cross-sectional structural view of a first embodiment of a semiconductor device.

FIGS. 2A and 2B are a plan view and a cross-sectional structural view of a semiconductor device.

FIGS. 3A and 3B are a plan view and a cross-sectional structural view of another semiconductor device.

FIGS. 4A to 4c are a plan view and cross-sectional structural views of a second embodiment of a semiconductor device.

FIGS. 5A and 5B are diagrams showing a configuration of a third embodiment of an analog switch.

FIG. 6 is a diagram showing a configuration of a third embodiment of an ultrasound imaging device.

### DESCRIPTION OF THE EMBODIMENTS

Description will now be given in detail of the present invention by referring to the drawings.

### First Embodiment

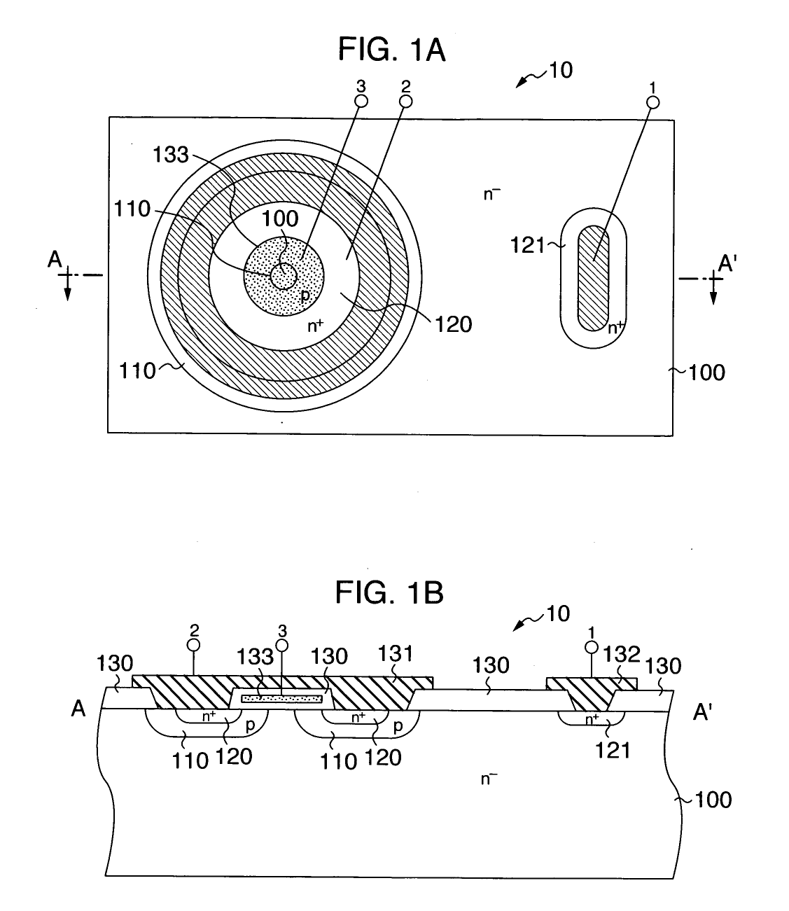

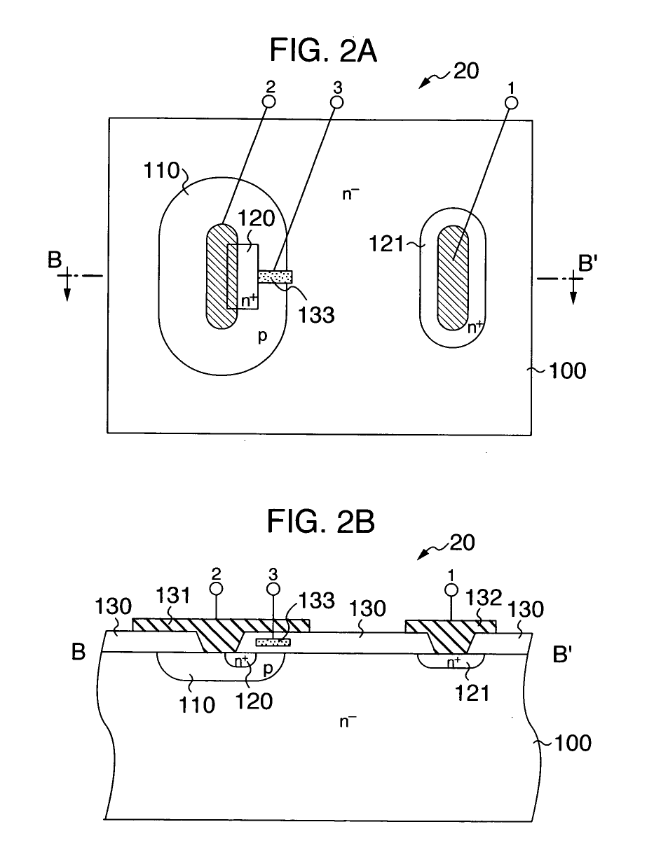

FIG. 1 shows the first embodiment of a semiconductor device. FIG. 1A shows a plan view of the embodiment and FIG. 1B shows a cross-sectional view along line AA′ of FIG. 1A. In FIGS. 1A and 1B, the same constituent components as those of FIGS. 2A and 2B are assigned with the same reference numerals.

The embodiment of the semiconductor device 10 shown in FIGS. 1A and 1B includes an n-type channel MOSFET formed on an n⁻-type silicon substrate 100. The MOSFET includes a p-type channel layer 110 having the shape of a ring in a plan view. A gate electrode 133 is arranged only on a central side of the p-type channel layer 110. A JFET resistor is integrally disposed in a region surrounded by the ring-shaped p-type channel layer 110.

In the embodiment of the n-type channel MOSFET, when a positive voltage is sufficiently applied across a gate terminal 3 and a source terminal 2, that is, the supplied voltage to the gate terminal 3 is larger than that to the source terminal 2, and a positive voltage is applied across a drain terminal 1 and the source terminal 2, that is, the supplied voltage to the drain terminal 1 is larger than that to the source terminal 2, a drain current flows from a drain electrode 132 to a source electrode 131 via an n⁺-type drain electrode contact layer 121, the n⁻-type silicon substrate 100, a central region surrounded by the ring-shaped p-type channel layer 110, a channel region formed beneath a gate electrode 133 and on a surface of the p-type channel layer 110, and an n⁺-type source electrode contact layer 120.

In the n-type channel MOSFET of the embodiment, the saturation current can be reduced by the JFET resistor appearing in a carrier depletion layer extending from the p-type channel layer 110 through a narrow current path surrounded by the p-type channel layer 110 to the n⁻-type silicon substrate 100. Since the JEFT resistor is loaded with most of the voltage applied between the drain terminal 1 and the source terminal 2, the voltage to be imposed on the channel region is lowered and hence the electric field is not concentrated onto the channel region. Since the JFET register adjusts the saturation current, the width of the gate electrode can be sufficiently secured and hence the electric field is not concentrated onto the channel region. This resultantly suppresses the creation of hot carriers and the aging of the n-type channel MOSFET of the embodiment. When compared with an associated device using a resistor other than the JFET resistor, for example, a resistor using a long n⁻-type drift layer and a polycrystalline silicon, the MOSFET of the embodiment is advantageous for the following reason. The MOSFET includes a vertical JFET resistor to reduce the element area on the semiconductor substrate, and hence the device size can be reduced for higher integration. The n-type channel MOSFET of the embodiment can be created using a small element area and is therefore particularly suitable to produce a high voltage analog switch on a dielectric isolation substrate or on a Silicon On Insulator (SOI) substrate including semiconductor islands insulation-isolated by insulator such as SiO₂.

The area enclosed by the ring-shaped p-type channel layer 110 can be adjusted according to the amount of the saturation current. That is, the shape of the area in a plan view can be a polygon and an ellipse in addition to a circle. Alternatively, the area may be a rectangle extending in one direction as well as a cross or a star having a shape extending in a plurality of directions. A shape of the area may be a race-track shape. Also, the area in a plan view may be a discontinuous shape in which at least one position is discontinuous in the p-type channel layer 110 and the n⁺-type source electrode contact layer 120. However, in the configuration of the discontinuous shape, it is required that the n⁺-type source electrode contact layer 120 is disposed within the p-type channel layer 110. The shape in a plan view of the gate electrode 133 can be appropriately adjusted according to the shape in a plan view of the p-type channel layer 110.

Description has been given of an embodiment of an n-type channel MOSFET on an n⁻-type substrate. It is also possible to similarly produce a p-type channel MOSFET on a p⁻-type substrate, which leads to an advantage similar to that of the n-type channel MOSFET on an n⁻-type substrate.

### Second Embodiment

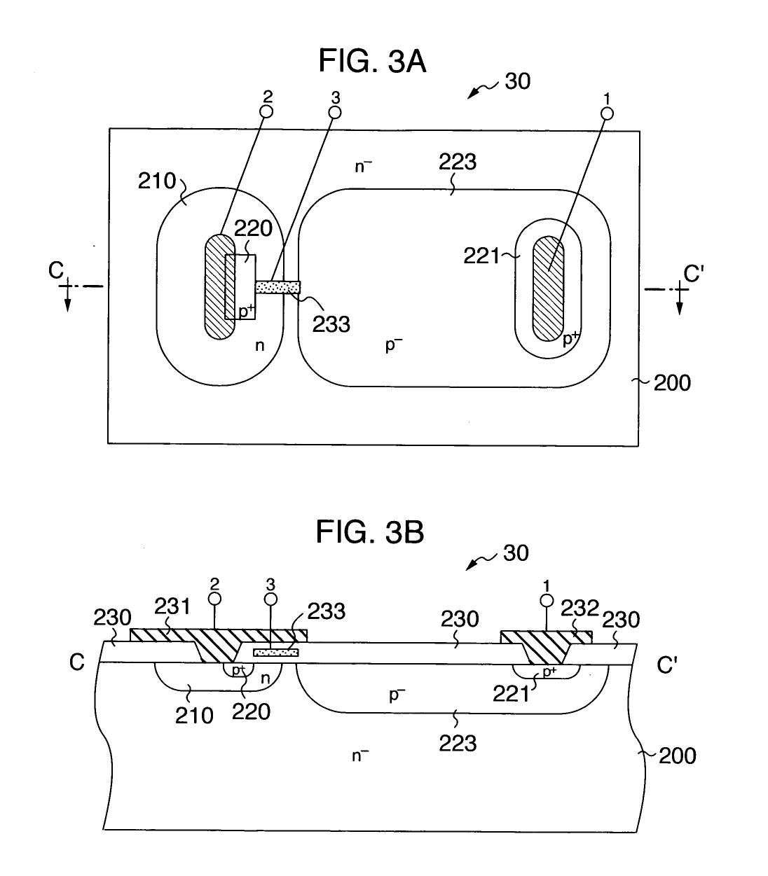

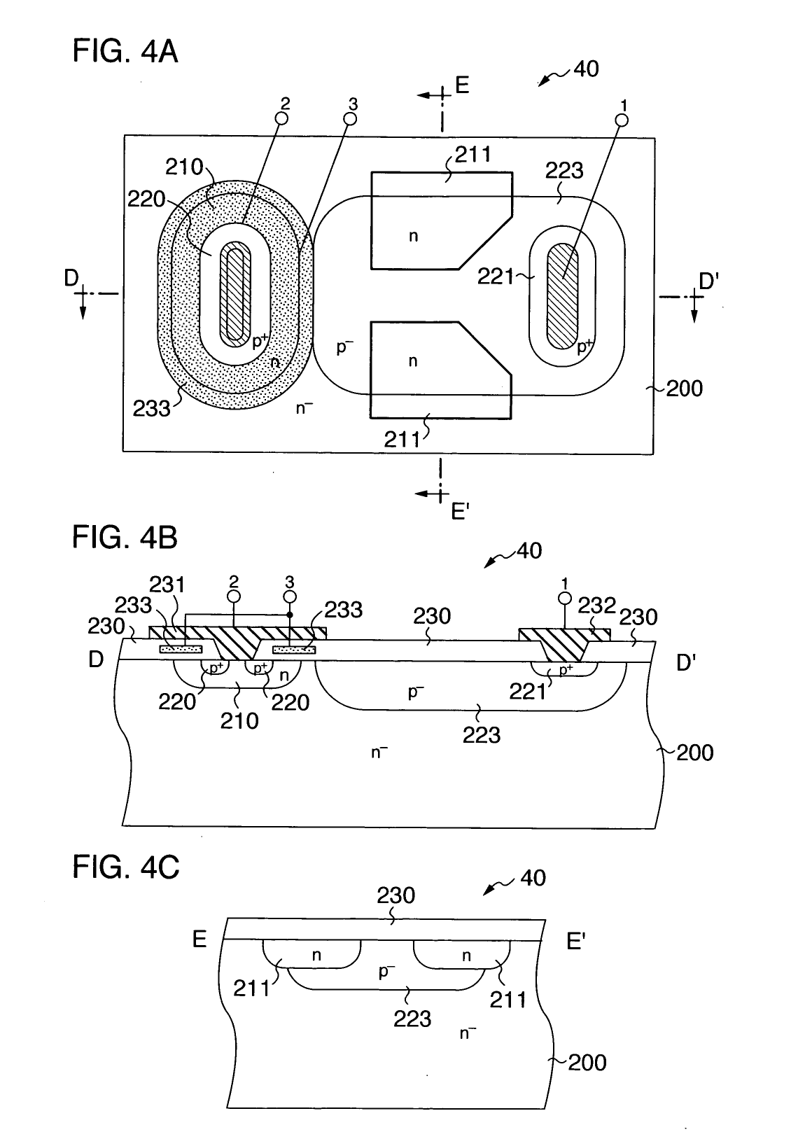

FIG. 4 shows a plan view and a cross-sectional structural view of a semiconductor device of the embodiment. FIG. 4A is a plan view of the device 40, FIG. 4B shows a cross section of the device along line DD′ of FIG. 4A, and FIG. 4C shows a cross section thereof along line EE′ of FIG. 4A. The configurations shown in FIGS. 4A to 4C include a p-type channel MOSFET formed on an n⁻-type silicon substrate. The MOSFET differs from that of FIG. 3 in that a JFET resistor is additionally disposed in the p⁻-type drift layer 223 by use of two JFET creating n-type layers 211 opposing each other and the gate electrode 233 extends to elongate the gate width.

In the second embodiment, when a sufficient negative voltage is applied across the gate terminal 3 and the source terminal 2 that is, the supplied voltage to the gate terminal 3 is smaller than that to the source terminal 2, and a negative voltage is applied across the drain terminal 1 and the source terminal 2, that is, the supplied voltage to the drain terminal 1 is smaller than that of the source terminal 2, a drain current flows from a drain electrode 232 to a source electrode 231 via a p⁺-type drain electrode contact layer 221, a p⁻-type drift layer including a region sandwiched between two JFET resistor creating n-type layers 211, a channel region beneath a gate electrode 233 on surfaces of the n⁻-type silicon substrate 200 and an n-type channel layer 210, and an p⁺-type source electrode contact layer 220.

In the second embodiment, the saturation current can be lowered in a narrow current path enclosed by the two JFET resistor creating n-type layers 211 by use of a JFET resistor created in a carrier depletion layer extending from the n⁻-type silicon substrate 200 and two n-type layers 211 to the p⁻-type drift layer 223. In the embodiment, since the JEFT resistor is loaded with most of the voltage applied between the drain terminal 1 and the source terminal 2, the voltage to be imposed on the channel region is reduced and hence the electric field is not concentrated onto the channel region. Since the JFET register adjusts the saturation current, the width of the gate electrode can be sufficiently secured and hence the electric field is not concentrated onto the channel region. This resultantly suppresses the creation of hot carriers and the aging of the MOSFET. When compared with an associated device using a resistor other than the JFET resistor, for example, a resistor using a long p⁻-type drift layer and polycrystalline silicon, the MOSFET of the embodiment is advantageous for the following reason. The MOSFET includes a high resistance JFET resistor to reduce the element area on the semiconductor substrate, and hence the device size can be reduced for higher integration. The p-type channel MOSFET of the embodiment can be created using a small element area and is therefore particularly suitable to produce a high voltage analog switch on a dielectric isolation substrate or on an SOI substrate including semiconductor islands insulation-isolated by insulator such as SiO₂.

The shape in a plan view of each of the two JFET resistor creating n-type layers 211 can be arbitrarily determined and is, for example, a polygon with rounded corners in addition to the polygon shown in FIG. 4A. The width and the length of the region enclosed by the n-type layers 211 and the area of the region can be adjusted according to the amount of saturation current. The shape of the region in a plan view can be the shape like a meandering region in addition to the shape like an arbitrary straight region. The electric field is likely concentrated onto an end region on the drain side of the current path sandwiched by the two n-type layers 211 to lower the voltage limit of MOSFET. Therefore, as can be seen from FIGS. 4A, it is favorable that the corners thereof have an obtuse angle equal to or more than 90 degrees or each corner is formed in the shape of an arc.

The JFET resistor creating n-type layer 211 can also be subdivided into at least two areas. There may also be arranged a plurality of current paths enclosed by the JFET resistor creating n-type layers 211 in the p-type drift layer 223. However, it is required that the layers 211 are at a potential substantially equal to that of the source electrode. In the embodiment of FIG. 4, the n-type layer 211 is connected via the n⁻-type silicon substrate 200 and the n-type channel layer 210 to the source electrode 231. Furthermore, exclusively for the JFET resistor creating n-type layer 211, there may be formed a contact point to make contact with the source electrode.

Description has been given of an embodiment of a p-type channel MOSFET on an n⁻-type substrate. It is also possible to similarly produce an n-type channel MOSFET on a p⁻-type substrate, which leads to almost the same advantage as for the p-type channel MOSFET on an n⁻-type substrate.

### Third Embodiment

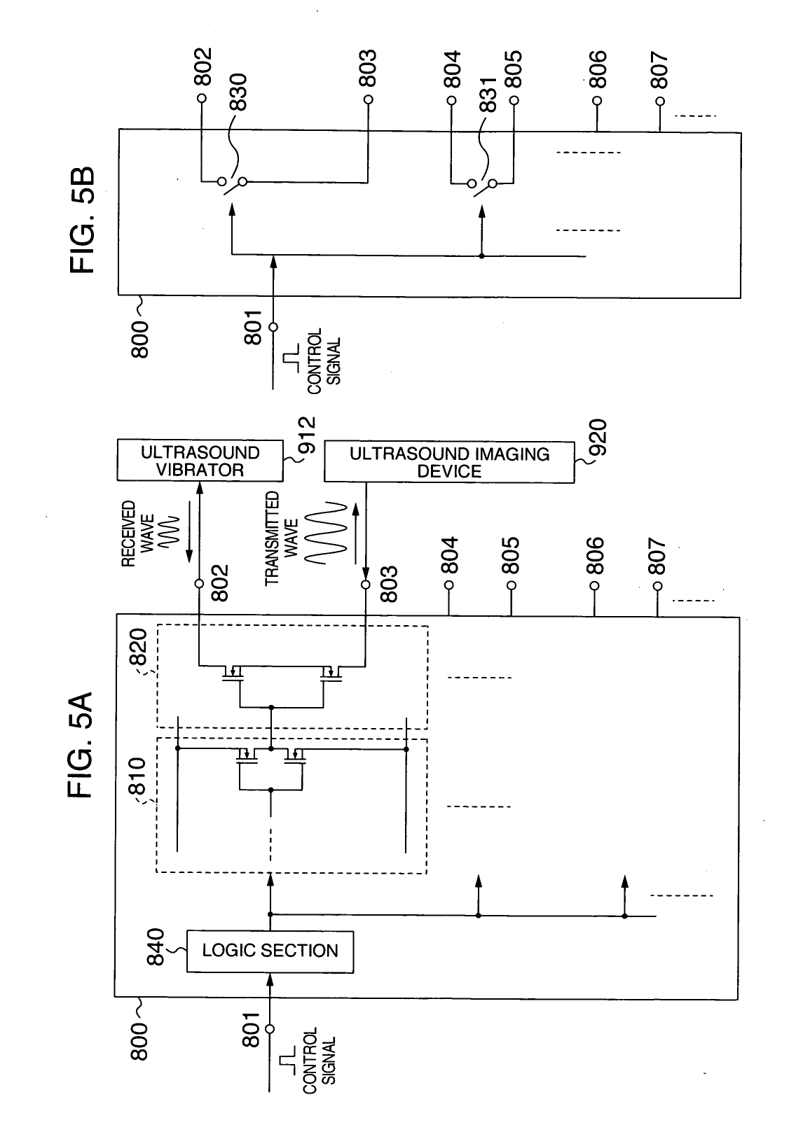

FIG. 5 shows the third embodiment of an analog switch IC in which FIG. 5A is a schematic circuit diagram to explain the configuration of the IC and FIG. 5B schematically shows an equivalent circuit diagram of the IC. In FIG. 5A, the analog switch IC 800 includes a control terminal 801, input/output (I/O) terminals 802 to 807, a driver stage circuit section 810, an output stage section 820, switches 830 and 831, a logic section 840, a fine vibrator 912 and an ultrasound imaging device 920. In the third embodiment, the drive stage circuit section 810 of the analog switch IC 800 shown in FIG. 5 includes the MOSFET with a reduced saturation current according to the first or second embodiment. This resultantly prevents the event in which noise caused by the leakage current from the drive stage circuit section 810 is outputted from the I/O terminals 802 and 803. It is also possible to reduce the aging of the MOSFET associated with an event of creation of hot carriers which possibly takes place in an analog switch IC including a conventional MOSFET with a reduced saturation current, i.e., the MOSFET shown in FIG. 2 or 3. As a result, reliability of the analog switch IC can be much more improved.

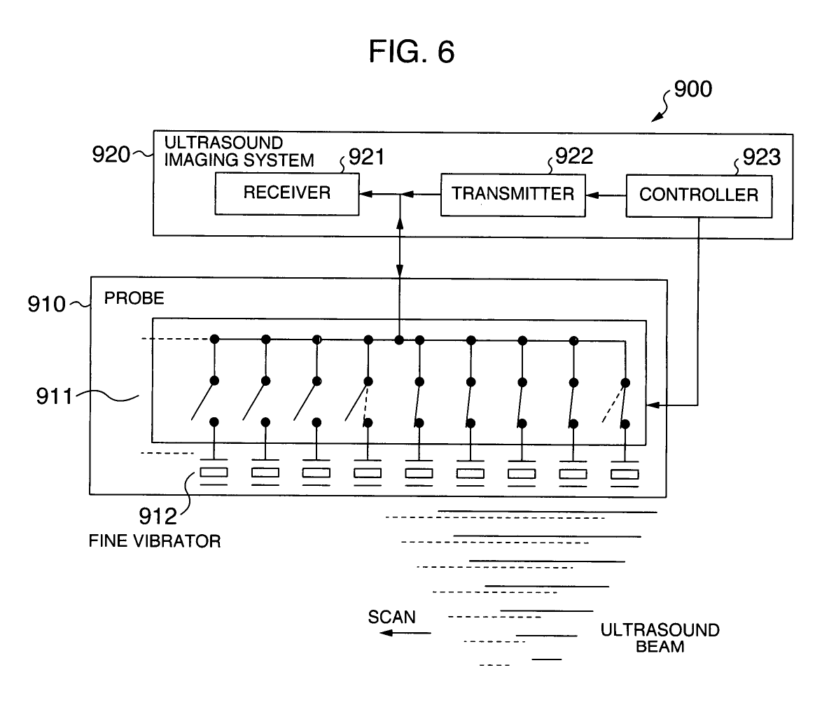

FIG. 6 shows structure of an ultrasound imaging system according to the third embodiment. The system configuration includes an ultrasound imaging system 900, an ultrasound probe 910, an analog switch IC 911 employed in the first and second embodiments, a fine vibrator 912, an ultrasound imaging device 920, an ultrasound wave receiver 921, an ultrasound wave transmitter 922, and a controller 923. In the ultrasound imaging system 910, an ultrasound signal is transmitted from the ultrasound wave transmitter 922 to the ultrasound probe 910 in response to a control signal at the controller 923. The signal consequently transmitted to each of the ultrasound probe 910 via an analog switch IC 911, and an ultrasound signal can be generated. The generated ultrasound signal is reflected at an object to be probed, received by a fine vibrator 912. The received ultrasound signal is forwarded through the analog switch IC 911 and consequently received and amplified by the ultrasound wave receiver 921 provided within the ultrasound device 920. The ultrasound signal is finally outputted as an image signal. Each of the arranged fine vibrators 912 selectively operates for receiving or transmitting the signal in accordance with switching operations of the analog switch IC 911. That is, an ultrasound signal shown “b” in the drawing of FIG. 6 is scanned as shown “a” in the drawing in accordance with ON/OFF operation of each of switching elements within the analog switch IC 911.

In the ultrasound imaging system adopting the analog switch IC 911 according to the first or second embodiment, the noise taking place at change-over of the switch can be lowered. This makes it possible for the system to produce a clear image while reducing deterioration with the passage of time in the control performance and picture quality.

The analog switch IC 800 of the present invention can also be employed for apparatuses including a plasma display, printers such as an ink-jet printer and a laser beam printer, and a tester to evaluate a printed circuit board. This leads to reduction of output noise, prevention of erroneous operations, and suppression of deterioration due to the aging to thereby improve reliability of the apparatuses using the analog switch IC 800 as in the case of the ultrasound imaging systems.

It should be further understood by those skilled in the art that although the foregoing description has been made on embodiments of the invention, the invention is not limited thereto and various changes and modifications may be made without departing from the spirit of the invention and the scope of the appended claims.

1. In a semiconductor switching element, a semiconductor device comprising a Junction-Field-Effect-Transistor (JFET) in a current conduction path, wherein the device is integrally disposed in the element such that:
when a voltage between a drain electrode and a source electrode increases in a conductive state of the switching element, resistance of the JFET increases.

2. A semiconductor device, comprising:
a semiconductor substrate of a first conductivity type;
a first semiconductor region of a second conductivity type formed in a ring shape in a semiconductor region of the semiconductor substrate, the first semiconductor region beginning at a first surface of the semiconductor substrate;
a ring-shaped second semiconductor region of a first conductivity type formed in the first semiconductor region, the second semiconductor region beginning at the first surface of the semiconductor substrate;
a third semiconductor region of a first conductivity type existing outside a region enclosed by the first semiconductor region;
a gate insulation film formed on the first surface in a region enclosed by the second semiconductor region;
a gate electrode formed on the gate insulation film;
a source electrode in contact with the first and second semiconductor regions with low resistance; and
a drain electrode in contact with the third semiconductor region with low resistance.

3. A semiconductor device according to claim 2, wherein the ring-shaped second semiconductor region is subdivided at at least one position into a plurality of regions in a discontinuous form.

4. A semiconductor device according to claim 3, wherein the first semiconductor region is subdivided at at least one position into a plurality of regions in a discontinuous form.

5. A semiconductor device according to claim 2, wherein the gate electrode, the source electrode, and the drain electrode are disposed on the first surface of the semiconductor substrate.

6. A semiconductor device according to claim 2, wherein the semiconductor substrate is a dielectric isolation substrate including a semiconductor island insulation-isolated by insulator.

7. A semiconductor device, comprising:
a semiconductor substrate of a first conductivity type;
a first semiconductor region of a second conductivity type formed in a semiconductor region of the semiconductor substrate, the first semiconductor region beginning at a first surface of the semiconductor substrate;
a second semiconductor region of a first conductivity type formed in a first region including an inside region and an outside region of the first semiconductor region, the second semiconductor region beginning at the first surface of the semiconductor substrate;
a third semiconductor region of a first conductivity type formed in a first region other than the second region, the third region including an inside region and an outside region of the first semiconductor region, the third semiconductor region beginning at the first surface of the semiconductor substrate and opposing the second semiconductor region in the first semiconductor region;
a fourth semiconductor region of a second conductivity type existing in the first semiconductor region;
a fifth semiconductor region of a first conductivity type formed in the semiconductor region of the semiconductor substrate beginning at a surface of the semiconductor substrate, the fifth semiconductor region opposing the fourth semiconductor region via the second and the third semiconductor regions;
a sixth semiconductor region of a second semiconductor type formed in the fifth semiconductor region;
a gate insulation film formed on the first surface of the semiconductor substrate in the fifth semiconductor region outside the sixth semiconductor region,
a gate electrode formed on the gate insulation film;
a source electrode in contact with the fifth and sixth semiconductor regions with low resistance; and
a drain electrode in contact with the fourth semiconductor region with low resistance.

8. A semiconductor device according to claim 7, wherein:
the second and third semiconductor regions exist in an inside region inside the first semiconductor region, not in a region including an inside region and an outside region of the first semiconductor region, the semiconductor device further comprising:
a seventh semiconductor region of a first conductivity type in the second semiconductor region; and
an eighth semiconductor region of a first conductivity type in the third semiconductor region, the source electrode being in contact with, in addition to the fifth and sixth semiconductor regions, the seventh and eighth semiconductor regions with low resistance.

9. A semiconductor device according to claim 7, wherein the gate electrode, the source electrode, and the drain electrode are disposed on the first surface of the semiconductor substrate.

10. A semiconductor device according to claim 7, wherein the semiconductor substrate is a dielectric isolation substrate including a semiconductor island insulation-isolated by insulator.

11. An ultrasound imaging system, comprising:
a system body including an ultrasound transmitting section, an ultrasound receiving section, and a control section to control the ultrasound transmitting and receiving sections; and
a probe connected to the system body for transmitting and/or receiving an ultrasound wave, wherein:
the probe includes a plurality of vibrators and an analog switch IC including a plurality of analog switches connected to the plural vibrators;
the analog switch IC includes an output stage section to connect the vibrators to the system body and a drive stage section to drive the output stage section by use of a signal from the control section; and
the drive stage section comprises a semiconductor device including:
a semiconductor substrate of a first conductivity type;
a first semiconductor region of a second conductivity type formed in a ring shape in a semiconductor region of the semiconductor substrate, the first semiconductor region beginning at a first surface of the semiconductor substrate;
a ring-shaped second semiconductor region of a first conductivity type formed in the first semiconductor region, the second semiconductor region beginning at the first surface of the semiconductor substrate;
a third semiconductor region of a first conductivity type existing outside a region enclosed by the first semiconductor region;
a gate insulation film formed on the first surface in a region enclosed by the second semiconductor region;
a gate electrode formed on the gate insulation film;
a source electrode in contact with the first and second semiconductor regions with low resistance; and
a drain electrode in contact with the third semiconductor region with low resistance.
